(19) United States
(12) Patent Application Publication
(10) Pub. No.: US 2011/0204986 A1
(43) Pub. Date: Aug. 25, 2011

(54) METHOD OF MANUFACTURING PACKAGE, PIEZOELECTRIC VIBRATOR, OSCILLATOR, ELECTRONIC DEVICE, AND RADIO-CONTROLLED TIMEPIECE

(76) Inventor: Yoichi Funabiki, Chiba-shi (JP)

(21) Appl. No.: 13/033,350

(22) Filed: Feb. 23, 2011

(30) Foreign Application Priority Data
Feb. 23, 2010 (JP) 2010-037986

(51) Int. Cl. H03B 5/32; H01L 41/053; H01L 41/22

(52) U.S. Cl. 331/158; 310/344; 29/25.35

(57) ABSTRACT

Provided are a method of manufacturing a package capable of forming a penetration electrode without conduction defects while maintaining the airtightness of a cavity by suppressing the occurrence of voids in a baked glass, a piezoelectric vibrator manufactured by the manufacturing method, and an oscillator, an electronic apparatus, and a radio-controlled timepiece each having the piezoelectric vibrator. The package manufacturing method includes a second glass frit filling step of filling a second glass frit in a penetration hole to be overlapped on a first glass frit and temporarily drying the second glass frit; and a baking step of baking and curing the first and second glass frits filled in the penetration hole. The second particle size of the second glass particles contained in the second glass frit is larger than the first particle size of the first glass particles contained in the first glass frit.

### RELATED APPLICATIONS

This application claims priority under 35 U.S.C. §119 to Japanese Patent Application No. 2010-037986 filed on Feb. 23, 2010, the entire content of which is hereby incorporated by reference.

### BACKGROUND OF THE INVENTION

1. Field of the Invention

The present invention relates to a method of manufacturing a package, a piezoelectric vibrator, and an oscillator, an electronic apparatus, and a radio-controlled timepiece each having the piezoelectric vibrator.

2. Description of the Related Art

Recently, a piezoelectric vibrator utilizing quartz or the like has been used in cellular phones and portable information terminals as the time source, the timing source of a control signal, a reference signal source, and the like. Although there are various piezoelectric vibrators of this type, a two-layered surface mounted device-type piezoelectric vibrator is one known example thereof.

The piezoelectric vibrator of this type has a two-layered structure in which a first substrate and a second substrate are directly bonded and packaged, and a piezoelectric vibrating reed is accommodated in a cavity formed between the two substrates. As an example of such a two-layered piezoelectric vibrator, a piezoelectric vibrator in which piezoelectric vibrating reeds sealed in the inner side of a cavity and outer electrodes formed on the outer side of the base substrate are electrically connected by penetration electrodes formed on the base substrate is known (for example, see JP-A-2002-124845).

In the two-layered piezoelectric vibrator, the penetration electrodes perform two major roles of electrically connecting the piezoelectric vibrating reeds and the outer electrodes to each other and blocking the penetration holes to maintain the airtightness of the cavity. Particularly, if the adhesion between the penetration electrode and the penetration hole is not sufficient, there is a possibility that the airtightness of the cavity is impaired. In order to eliminate such an inconvenience, it is necessary to form the penetration electrode in a state where the penetration electrode is tightly and closely adhered to the inner circumferential surface of the penetration hole to completely block the penetration hole.

However, in JP-A-2002-124845, it is described that the penetration electrode is formed by using a pin member (corresponding to a metal pin of the present invention) made of a metal as a conductive member. As a specific method of forming the penetration electrode, it is described that after a base substrate wafer later serving as a base substrate is heated, the pin member is inserted into the penetration hole when the base substrate wafer is thermally softened.

However, according to the method of forming the penetration electrode by inserting the pin member into the penetration hole as disclosed in JP-A-2002-124845, it is difficult to completely block the gap between the pin member and the penetration hole. Therefore, there is a possibility that the airtightness of the cavity is not secured. Moreover, a number of penetration holes are formed in the base substrate wafer. Thus, a number of steps are required to insert the pin members into all penetration holes when the base substrate wafer is thermally softened.

In order to solve the above-described problem, a method of forming the penetration electrode using a conductive metal pin and a glass frit is proposed. As a specific penetration electrode forming method, first, a glass frit is filled into a gap between the penetration hole and the metal pin in a state where the metal pin standing from a flat plate-like base portion is inserted into the penetration hole (corresponding to a recess portion of the present invention). The glass frit is mainly made up of powder-like glass particles and an organic solvent which is a solvent. Moreover, after the filled glass frit is baked so that the penetration hole, the metal pin, and the glass frit are integrated with each other, the base portion is polished and removed, whereby the penetration electrode is formed.

The baking of the glass frit is performed by putting a base substrate wafer in which the glass frit is filled into a baking furnace and maintaining the base substrate wafer under a predetermined atmospheric temperature for a predetermined period. Since the glass particles are melted by baking the glass frit and the gap between the glass particles is blocked, it is possible to completely block the penetration hole in a tightly adhered state. When the glass frit is baked, organic components contained in the glass frit are evaporated, and gases are generated in the glass frit. These gases are discharged outside from an exposed portion on the outer side of the glass frit.

However, when baking is performed by putting the base substrate wafer into the baking furnace and maintaining the base substrate wafer under a predetermined atmospheric temperature as described above, since the glass frit filled in the penetration hole is heated from the outer side, the baking proceeds from the outer side of the glass frit toward the inner side. At that time, since the baked glass frit on the outer side acts as a lid, it is hard for the gases generated in the glass frit to be discharged outside. Moreover, when the baking of the glass frit is completed at this stage, there is a possibility that bubbles generated by the gases will remain in the glass frit and voids are formed in the glass after the glass frit baking. Moreover, there is a possibility that the penetration hole and the metal pin are not closely adhered to the baked glass due to the voids, and the airtightness of the cavity is impaired. Moreover, when the base portion is removed to form a penetration electrode, a recess portion is formed on the surface of the penetration electrode due to the voids. When an electrode film is formed on the recess portion, there is a possibility that since the thickness at the periphery of the recess portion is small, the electrode film is easily broken, and reliable conduction of the penetration electrode is not secured.

### SUMMARY OF THE INVENTION

The present invention has been made in view of the above problems, and an object of the present invention is to provide a method of manufacturing a package capable of forming a penetration electrode without conduction defects while maintaining the airtightness of a cavity by suppressing the occurrence of voids in a baked glass. Another object of the present invention is to provide a piezoelectric vibrator manufactured by the manufacturing method, and an oscillator, an electronic apparatus, and a radio-controlled timepiece each having the piezoelectric vibrator.

According to an aspect of the present invention, there is provided a method of manufacturing a package capable of sealing an electronic component in a cavity which is formed between a plurality of substrates bonded to each other, the method including a penetration electrode forming step of forming a penetration electrode so as to penetrate a first substrate of the plurality of substrates in a thickness direction thereof so that the inner side of the cavity and the outer side of the package are electrically connected to each other. The penetration electrode forming step includes a recess portion forming step of forming a recess portion having a first opening on a first surface of the first substrate; a metal pin disposing step of inserting a metal pin into the recess portion; a first glass frit filling step of filling a first glass frit in the recess portion and temporarily drying the first glass frit; a second glass frit filling step of filling a second glass frit in the recess portion to be overlapped on the first glass frit and temporarily drying the second glass frit; a baking step of baking and curing the first and second glass frits filled in the recess portion; and a polishing step of polishing at least a second surface of the first substrate so as to expose the metal pin to the second surface. A second particle size of second glass particles contained in the second glass frit is larger than a first particle size of first glass particles contained in the first glass frit.

According to this configuration, since the second particle size of the second glass particles is larger than the first particle size of the first glass particles, the heat capacity of the second glass particles is larger than the heat capacity of the first glass particles. Therefore, in the baking step, the melting of the second glass particles is completed later than the melting of the first glass particles. Moreover, since the second glass frit is filled to be overlapped on the first glass frit, the first glass frit is filled on the bottom side of the recess portion, and the second glass frit is filled on the first opening side of the recess portion. Therefore, the gases generated from the first glass frit pass through the gap between the second glass particles and are discharged outside from the first opening of the recess portion while preventing the second glass frit from acting as a lid. Because of this, since it is hard for the bubbles generated by the gases to remain in the first and second glass frits, it is possible to prevent the occurrence of voids in the glass after the baking. Therefore, since the recess portion and the metal pin are effectively and closely adhered to the baked glass without generating voids, it is possible to form the penetration electrode without conduction defects while maintaining the airtightness of the cavity.

It is preferable that a viscosity of the first glass frit is equal to or smaller than a viscosity of the second glass frit.

According to this configuration, since the first glass frit having a low viscosity is filled first, the first glass frit can be dispersed over a wide area to every corner in the recess portion. Therefore, it is possible to suppress the occurrence of voids in the recess portion at the time of filling the first glass frit.

It is preferable that the recess portion is formed so that the inner shape gradually increases from the second surface side towards the first surface side.

According to this configuration, since the inner shape of the first opening is large, the gases generated in the first and second glass frits can be easily discharged outside from the exposed portion on the outer side of the second glass frit. Moreover, by filling the glass frit from the first opening, the glass frit can be easily filled in the gap between the recess portion and the metal pin.

According to another aspect of the present invention, there is provided a piezoelectric vibrator in which a piezoelectric vibrating reed is sealed in the cavity of the package manufactured by the package manufacturing method as the electronic component.

According to this configuration, since the piezoelectric vibrator is sealed in the package which is manufactured by a manufacturing method capable of securing reliable conduction of the penetration electrode while maintaining the airtightness of the cavity, a piezoelectric vibrator having excellent performance and superior reliability can be provided.

According to another aspect of the invention, there is provided an oscillator in which the above-described piezoelectric vibrator is electrically connected to an integrated circuit as an oscillating piece.

According to still another aspect of the invention, there is provided an electronic apparatus in which the above-described piezoelectric vibrator is electrically connected to a clock section.

According to still another aspect of the invention, there is provided a radio-controlled timepiece in which the above-described piezoelectric vibrator is electrically connected to a filter section.

Since each of the oscillator, electronic device, and radio-controlled timepiece of the above aspects of the present invention includes the piezoelectric vibrator which is manufactured by a manufacturing method capable of securing reliable conduction of the penetration electrode while maintaining the airtightness of the cavity, an oscillator, an electronic device, and a radio-controlled timepiece having excellent performance and superior reliability can be provided.

According to this configuration, since the second particle size of the second glass particles is larger than the first particle size of the first glass particles, the heat capacity of the second glass particles is larger than the heat capacity of the first glass particles. Therefore, in the baking step, the melting of the second glass particles is completed later than the melting of the first glass particles. Moreover, since the second glass frit is filled to be overlapped on the first glass fit, the first glass frit is filled on the bottom side of the recess portion, and the second glass frit is filled on the first opening side of the recess portion. Therefore, the gases generated from the first glass frit pass through the gap between the second glass particles and are discharged outside from the first opening of the recess portion while preventing the second glass frit from acting as a lid. In this way, since it is hard for bubbles generated by the gases to remain in the first and second glass frits, it is possible to prevent the occurrence of voids in the glass after the baking. Therefore, since the recess portion and the metal pin are effectively and closely adhered to the baked glass without generating voids, it is possible to form the penetration electrode without conduction defects while maintaining the airtightness of the cavity.

### BRIEF DESCRIPTION OF THE DRAWINGS

FIG. 1 is a perspective view showing an external appearance of a piezoelectric vibrator according to an embodiment of the present invention.

FIG. 2 is a top view showing an inner structure of the piezoelectric vibrator shown in FIG. 1, showing a state where a lid substrate is removed.

FIG. 3 is a sectional view of the piezoelectric vibrator taken along the line A-A in FIG. 2.

FIG. 4 is an exploded perspective view of the piezoelectric vibrator shown in FIG. 1.

FIG. 5 is a top view of a piezoelectric vibrating reed.

FIG. 6 is a bottom view of the piezoelectric vibrating reed.

FIG. 7 is a sectional view taken along the line B-B in FIG. 5.

FIG. 8 is a flowchart of the manufacturing method of a piezoelectric vibrator.

FIG. 9 is an exploded perspective view of a wafer assembly.

FIG. 10 is a diagram illustrating a penetration hole.

FIGS. 11A and 11B are diagrams illustrating a metal pin, in which FIG. 11A is a perspective view and FIG. 11B is a sectional view taken along the line C-C in FIG. 11A.

FIGS. 12A and 12B are diagrams illustrating a metal pin disposing step.

FIGS. 13A and 13B are diagrams illustrating a first glass frit filling step, in which FIG. 13A shows a state where a first glass frit is being filled and FIG. 13B shows a state after the glass frit is temporarily dried.

FIGS. 14A and 14B are diagrams illustrating a second glass frit filling step, in which FIG. 14A shows a state where a second glass frit is being filled and FIG. 14B shows a state after the glass frit is temporarily dried.

FIG. 15 is a diagram illustrating a baking step.

FIG. 16 is a diagram showing the configuration of an oscillator according to an embodiment of the present invention.

FIG. 17 is a diagram showing the configuration of an electronic apparatus according to an embodiment of the present invention.

FIG. 18 is a diagram showing the configuration of a radio-controlled timepiece according to an embodiment of the present invention.

### DETAILED DESCRIPTION OF THE PREFERRED EMBODIMENTS

### First Embodiment: Piezoelectric Vibrator

Hereinafter, a piezoelectric vibrator according to an embodiment of the present invention will be described with reference to the drawings.

In the following description, it is assumed that a first substrate is a base substrate, and a substrate bonded to the base substrate is a lid substrate. Moreover, it is assumed that an outer surface of the base substrate of a package (a piezoelectric vibrator) is a first surface L, and a bonding surface of the base substrate bonded to the lid substrate is a second surface U.

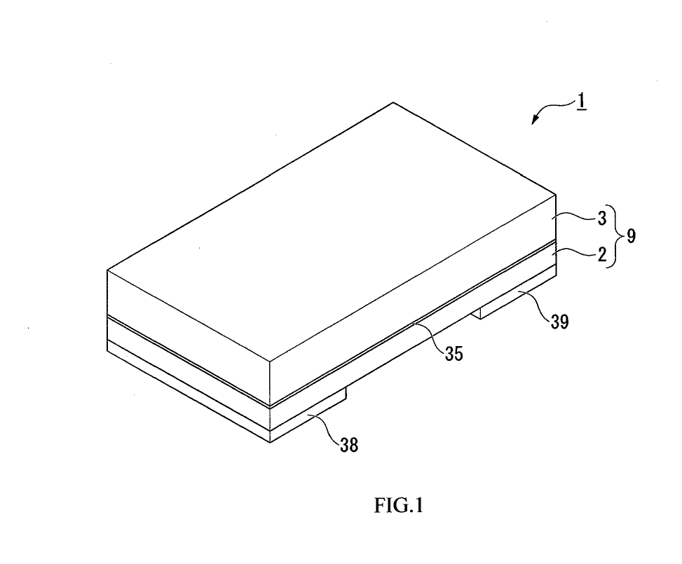

FIG. 1 is a perspective view showing an external appearance of a piezoelectric vibrator according to an embodiment of the present invention.

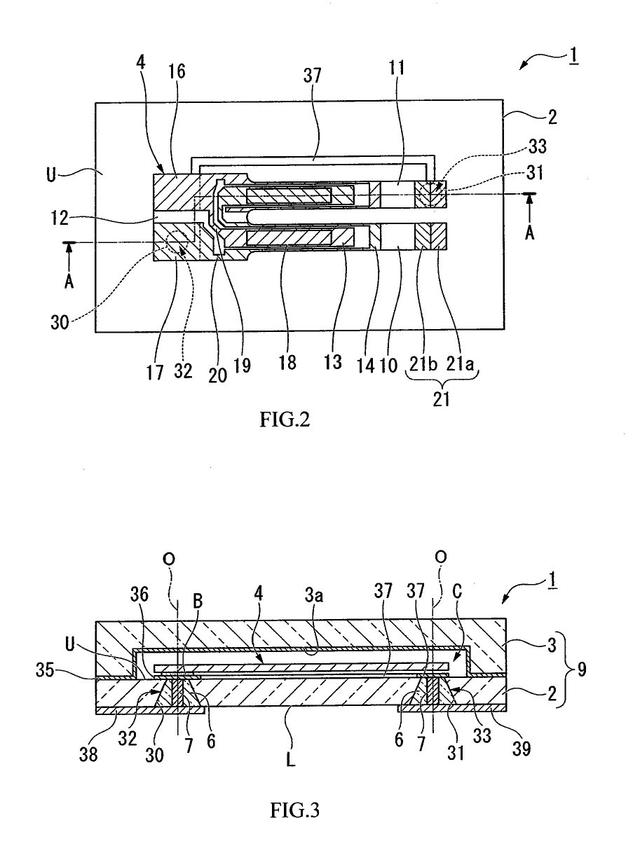

FIG. 2 is a top view showing an inner structure of the piezoelectric vibrator, showing a state where a lid substrate is removed.

FIG. 3 is a sectional view of the piezoelectric vibrator taken along the line A-A in FIG. 2.

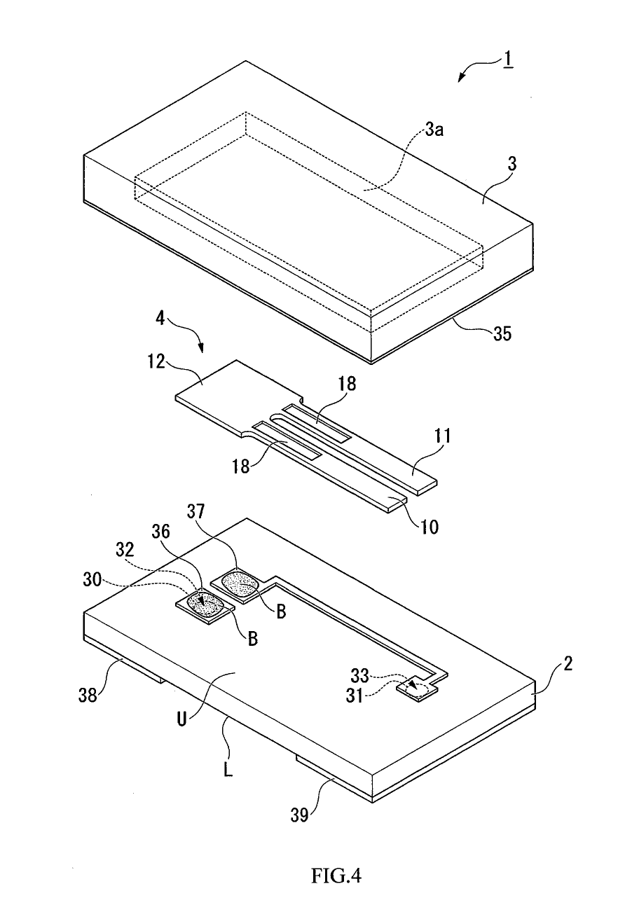

FIG. 4 is an exploded perspective view of the piezoelectric vibrator shown in FIG. 1.

In FIG. 4, for better understanding of the drawings, illustrations of the excitation electrode 15, extraction electrodes 19 and 20, mount electrodes 16 and 17, and weight metal film 21, which will be described later, are omitted.

As shown in FIGS. 1 to 4, a piezoelectric vibrator 1 according to the present embodiment is a surface mounted device-type piezoelectric vibrator 1 which includes a package 9, in which a base substrate 2 and a lid substrate 3 are anodically bonded to each other with a bonding film 35 disposed therebetween, and a piezoelectric vibrating reed 4 which is accommodated in a cavity C of the package 9.

### Piezoelectric Vibrating Reed

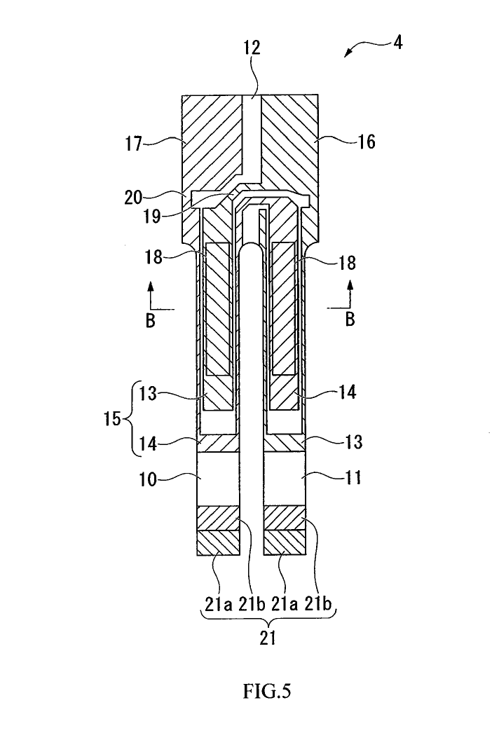

FIG. 5 is a top view of a piezoelectric vibrating reed.

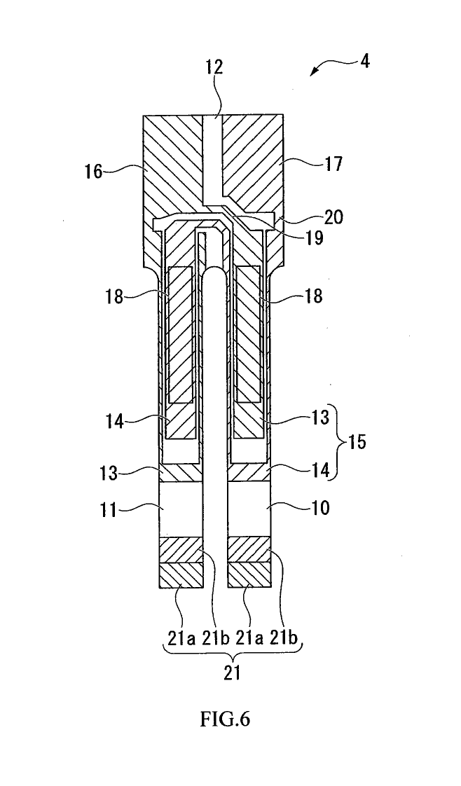

FIG. 6 is a bottom view of the piezoelectric vibrating reed.

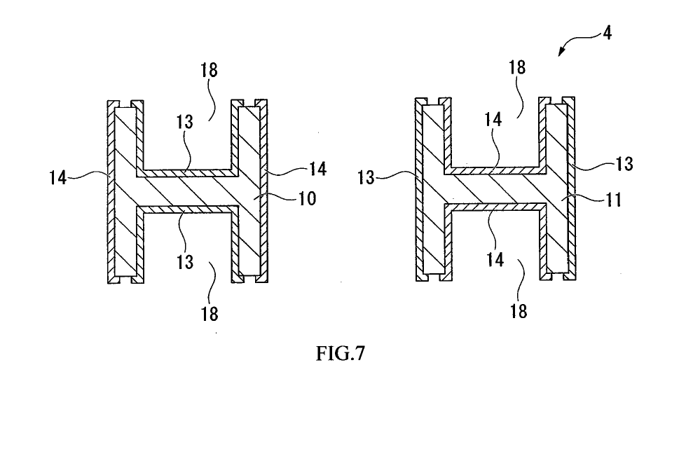

FIG. 7 is a sectional view taken along the line B-B in FIG. 5.

As shown in FIGS. 5 to 7, the piezoelectric vibrating reed 4 is a tuning-fork type vibrating reed which is made of a piezoelectric material such as crystal, lithium tantalate, or lithium niobate and is configured to vibrate when a predetermined voltage is applied thereto. The piezoelectric vibrating reed 4 includes a pair of vibrating arms 10 and 11 disposed in parallel to each other, a base portion 12 to which the base end sides of the pair of vibrating arms 10 and 11 are integrally fixed, and groove portions 18 which are formed on both principal surfaces of the pair of vibrating arms 10 and 11. The groove portions 18 are formed so as to extend from the base end sides of the vibrating arms 10 and 11 along the longitudinal direction of the vibrating arms 10 and 11 up to approximately the middle portions thereof.

The excitation electrode 15 and extraction electrodes 19 and 20 are formed by a single-layered film of chromium (Cr) which is the same material as the base layer of mount electrodes 16 and 17 described later. Therefore, it is possible to form the excitation electrode 15 and the extraction electrodes 19 and 20 at the same time as the forming of the base layer of the mount electrodes 16 and 17.

The excitation electrode 15 is an electrode that allows the pair of vibrating arms 10 and 11 to vibrate at a predetermined resonance frequency in a direction to move closer to or away from each other. The first excitation electrode 13 and second excitation electrode 14 that constitute the excitation electrode 15 are patterned and formed on the outer surfaces of the pair of vibrating arms 10 and 11 in an electrically isolated state.

The mount electrodes 16 and 17 of the present embodiment are laminated films of chromium (Cr) and gold (Au), which are formed by forming a chromium (Cr) film having good adhesion with quartz as a base layer and then forming a thin gold (Au) film on the surface thereof as a finishing layer.

The tip ends of the pair of the vibrating arms 10 and 11 are coated with a weight metal film 21 for adjustment (frequency tuning) of their own vibration states in a manner such as to vibrate within a predetermined frequency range. The weight metal film 21 is divided into a rough tuning film 21a used for tuning the frequency roughly and a fine tuning film 21b used for tuning the frequency finely. By tuning the frequency with the use of the rough tuning film 21a and the fine tuning film 21b, the frequency of the pair of the vibrating arms 10 and 11 can be set to fall within the range of the nominal frequency of the device.

### Package

As shown in FIGS. 1, 3, and 4, the base substrate 2 and the lid substrate 3 are substrates that can be anodically bonded and that are made of a glass material, for example, soda-lime glass, and are formed in a plate-like form. On a bonding surface side of the lid substrate 3 to be bonded to the base substrate 2, a recess portion 3a for a cavity is formed in which the piezoelectric vibrating reed 4 is accommodated.

A bonding film 35 for anodic bonding is formed on the entire surface on the bonding surface side of the lid substrate 3 to be bonded to the base substrate 2. That is to say, the bonding film 35 is formed in a frame region at the periphery of the recess portion 3a for the cavity in addition to the entire inner surface of the recess portion 3a for the cavity. Although the bonding film 35 of the present embodiment is made of a Si film, the bonding film 35 may be made of aluminum (Al) or Cr. As will be described later, the bonding film 35 and the base substrate 2 are anodically bonded, whereby the cavity C is vacuum-sealed.

As shown in FIG. 3, the piezoelectric vibrator 1 includes penetration electrodes 32 and 33 which penetrate through the base substrate 2 in the thickness direction thereof so that the inside of the cavity C is electrically connected to the outside of the piezoelectric vibrator 1. Moreover, each of the penetration electrodes 32 and 33 has a metal pin 7 which is disposed in the penetration holes (recess portions) 30 and 31 penetrating through the base substrate 2 so as to connect the piezoelectric vibrating reed 4 to the outside and a cylindrical member 6 which is filled between the penetration holes 30 and 31 and the metal pin 7.

As shown in FIGS. 2 and 3, the penetration holes 30 and 31 are formed so as to be received in the cavity C when the piezoelectric vibrator 1 is formed. More specifically, the penetration holes 30 and 31 of the present embodiment are formed such that one penetration hole 30 is positioned at a corresponding position close to the base portion 12 of the piezoelectric vibrating reed 4 which is mounted in a mounting step described later, and the other penetration hole 31 is positioned at a corresponding position close to the tip end sides of the vibrating arms 10 and 11. As shown in FIG. 3, the penetration holes 30 and 31 of the present embodiment are formed so that the inner shape thereof gradually increases from the second surface U side towards the first surface L side and the cross section including the central axis O of the penetration holes 30 and 31 has a tapered shape. The tapering angle of the inner circumferential surfaces of the penetration holes 30 and 31 is about 10° to 20° with respect to the central axis O of the penetration holes 30 and 31. Moreover, in the present embodiment, the cross section in the direction perpendicular to the central axis O of the penetration holes 30 and 31 has a circular shape.

Next, the penetration electrode will be described. In the following description, although only the penetration electrode 32 is described as an example, the same applies to the penetration electrode 33. Moreover, the same relationship between the penetration electrode 32, the lead-out electrode 36, and the outer electrode 39 applies to the relationship between the penetration electrode 33, the lead-out electrode 37, and the outer electrode 39.

As shown in FIG. 3, the penetration electrode 32 is formed by a metal pin 7 and a cylindrical member 6 which are disposed at the inner side of the penetration hole 30.

The metal pin 7 is a columnar member which has a diameter slightly smaller than the diameter on the second surface U side of the penetration hole 30 formed on the base substrate 2 and which has approximately the same length as the depth of the penetration hole 30.

The metal pin 7 is a conductive member formed of a metal material such as stainless steel, silver (Ag), Ni alloy, Al, and particularly, is preferably formed of an alloy (42 alloy) in which the iron (Fe) content is 58 wt % and the Ni content is 42 wt %. The metal pin 7 is formed by forging or press working.

In the present embodiment, the cylindrical member 6 is obtained by baking a first glass frit and a second glass frit described later. Specifically, the small-diameter side (the second surface U side) of the cylindrical member 6 is formed by baking the first glass fit, and the large-diameter side (the first surface L side) thereof is formed by baking the second glass frit. The cylindrical member 6 has a shape of which both ends are flat and which has approximately the same thickness as the base substrate 2. The metal pin 7 is disposed at the center of the cylindrical member 6 so as to penetrate through the cylindrical member 6, and the cylindrical member 6 is tightly attached to the metal pin 7 and the penetration hole 30. In this way, the cylindrical member 6 and the metal pin 7 serve to maintain the airtightness of the cavity C by completely closing the penetration hole 30 and also to make a lead-out electrode 36 and an outer electrode 38 described later electrically connected to each other.

As shown in FIGS. 2 to 4, a pair of lead-out electrodes 36 and 37 is patterned on the second surface U side of the base substrate 2. One lead-out electrode 36 among the pair of lead-out electrodes 36 and 37 is formed so as to be disposed right above one penetration electrode 32. Moreover, the other lead-out electrode 37 is formed so as to be disposed right above the other penetration electrode 33 after being led out from a position near one lead-out electrode 36 towards the tip end sides of the vibrating arms 10 and 11 along the vibrating arms 10 and 11.

Moreover, bumps B which have a tapered shape and are made from Au or the like are formed on the pair of lead-out electrodes 36 and 37, and the pair of mount electrodes of the piezoelectric vibrating reed 4 is mounted using the bumps B. In this way, one mount electrode 16 of the piezoelectric vibrating reed 4 is electrically connected to one penetration electrode 32 via one lead-out electrode 36, and the other mount electrode 17 is electrically connected to the other penetration electrode 33 via the other lead-out electrode 37.

Moreover, as shown in FIGS. 1, 3, and 4, a pair of outer electrodes 38 and 39 is formed on the first surface L of the base substrate 2. The pair of outer electrodes 38 and 39 is formed at both ends in the longitudinal direction of the base substrate 2 and is electrically connected to the pair of penetration electrodes 32 and 33, respectively.

When the piezoelectric vibrator 1 configured in this manner is operated, a predetermined drive voltage is applied to the outer electrodes 38 and 39 formed on the base substrate 2. In this way, a voltage can be applied to the excitation electrode 15 including the first and second excitation electrodes 13 and 14, of the piezoelectric vibrating reed 4, and the pair of vibrating arms 10 and 11 is allowed to vibrate at a predetermined frequency in a direction moving closer to or away from each other. This vibration of the pair of vibrating arms 10 and 11 can be used as the time source, the timing source of a control signal, the reference signal source, and the like.

### Piezoelectric Vibrator Manufacturing Method

Next, a method of manufacturing the above-described piezoelectric vibrator will be described with reference to a flowchart.

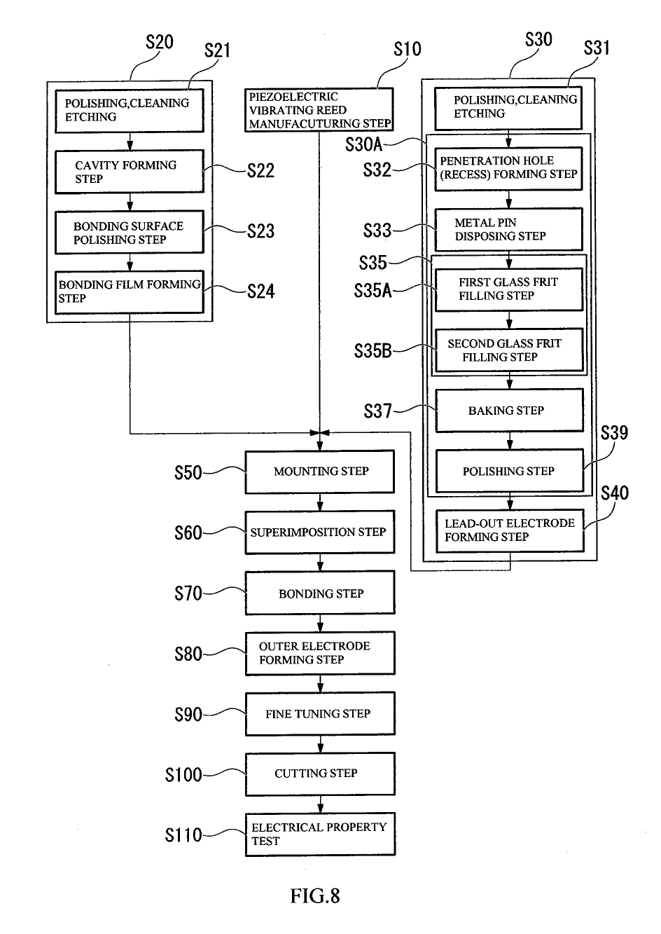

FIG. 8 is a flowchart of the manufacturing method of a piezoelectric vibrator according to the present embodiment.

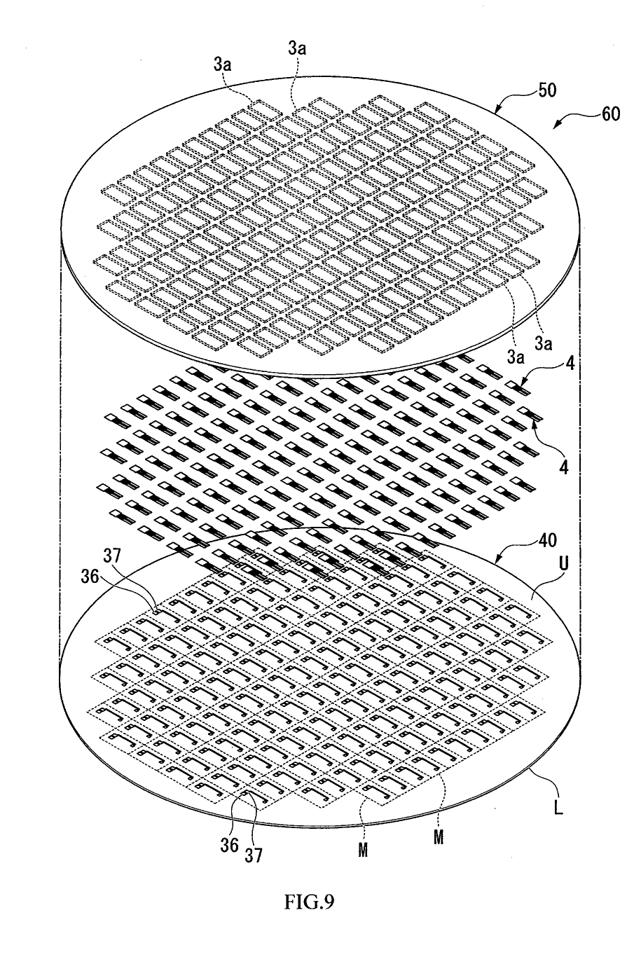

FIG. 9 is an exploded perspective view of a wafer assembly. The dotted line shown in FIG. 9 is a cutting line M along which a cutting step performed later is achieved.

The manufacturing method of the piezoelectric vibrator according to the present embodiment mainly includes a piezoelectric vibrating reed manufacturing step S10, a lid substrate wafer manufacturing step S20, a base substrate wafer manufacturing step S30, and an assembling step (S50 and subsequent steps). Among these steps, the piezoelectric vibrating reed manufacturing step S10, the lid substrate wafer manufacturing step S20, and the base substrate wafer manufacturing step S30 can be performed in parallel.

### Piezoelectric Vibrating Reed Manufacturing Step

In the piezoelectric vibrating reed manufacturing step S10, the piezoelectric vibrating reed 4 shown in FIGS. 5 to 7 is manufactured. Specifically, first, a rough Lambert crystal is sliced at a predetermined angle to obtain a wafer having a constant thickness. Subsequently, the wafer is subjected to crude processing by lapping, and an affected layer is removed by etching. Then, the wafer is subjected to mirror processing such as polishing to obtain a wafer having a predetermined thickness. Subsequently, the wafer is subjected to appropriate processing such as washing, and the wafer is patterned so as to have the outer shape of the piezoelectric vibrating reed 4 by a photolithography technique. Moreover, a metal film is formed and patterned on the wafer, thus forming the excitation electrode 15, the extraction electrodes 19 and 20, the mount electrodes 16 and 17, and the weight metal film 21. In this way, a plurality of piezoelectric vibrating reeds 4 can be manufactured. Subsequently, rough tuning of the resonance frequency of the piezoelectric vibrating reed 4 is performed. This rough tuning is achieved by irradiating the rough tuning film 21a of the weight metal film 21 with a laser beam to evaporate a part of the rough tuning film 21a, thus changing the weight of the vibrating arms 10 and 11.

### Lid Substrate Wafer Manufacturing Step

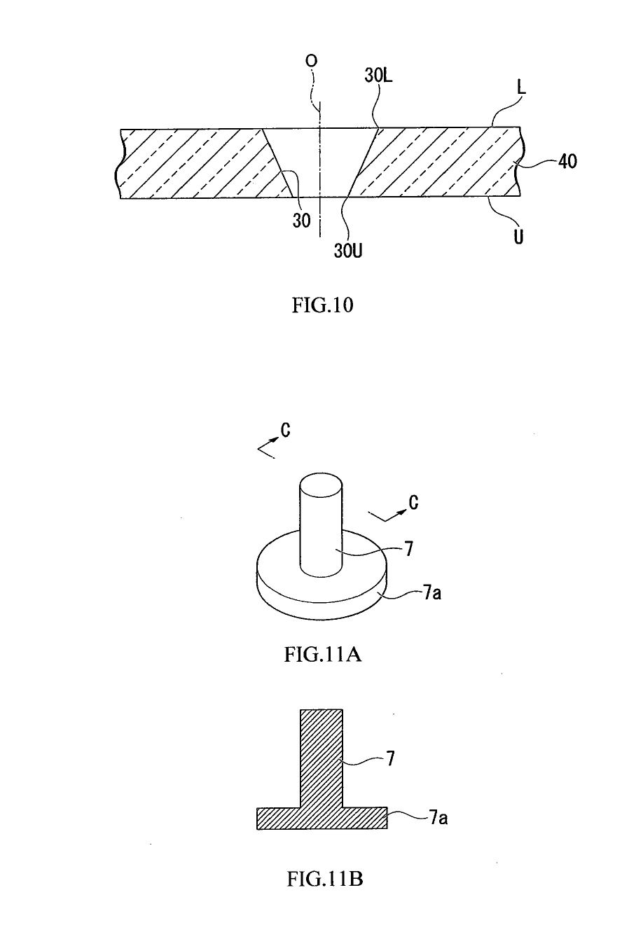

In the lid substrate wafer manufacturing step S20, as shown in FIG. 10, the lid substrate wafer 50 later serving as the lid substrate 3 is manufactured. First, a disk-shaped lid substrate wafer 50 made of a soda-lime glass is polished to a predetermined thickness and cleaned, and then, the affected uppermost layer is removed by etching or the like (S21). Subsequently, in a cavity forming step S22, a plurality of recess portions 3a for cavities is formed on a bonding surface of the lid substrate wafer 50 to be bonded to the base substrate wafer 40. The recess portions 3a for cavities are formed by heat-press molding, etching, or the like. After that, in a bonding surface polishing step S23, the bonding surface bonded to the base substrate wafer 40 is polished.

Subsequently, in a bonding film forming step S24, a bonding film 35 shown in FIGS. 1, 2, and 4 is formed on the bonding surface to be bonded to the base substrate wafer 40. The bonding film 35 may be formed on the entire inner surface of the cavity C in addition to the bonding surface to be bonded to the base substrate wafer 40. In this way, patterning of the bonding film 35 is not necessary, and the manufacturing cost can be reduced. The bonding film 35 can be formed by a film-formation method such as sputtering or CVD. Since the bonding surface polishing step S23 is performed before the bonding film forming step S24, the flatness of the surface of the bonding film 35 can be secured, and stable bonding with the base substrate wafer 40 can be achieved.

### Base Substrate Wafer Manufacturing Step

In a base substrate wafer manufacturing step S30, as shown in FIG. 9, the base substrate wafer 40 later serving as the base substrate is manufactured. First, a disk-shaped base substrate wafer 40 made of a soda-lime glass is polished to a predetermined thickness and cleaned, and then, the affected uppermost layer is removed by etching or the like (S31).

### Penetration Electrode Forming Step

Subsequently, a penetration electrode forming step S30A is performed in which the pair of penetration electrodes 32 and 33 is formed on the base substrate wafer 40. Hereinafter, the penetration electrode forming step S30A will be described. In the following description, although only the step of forming the penetration electrode 32 is described, the same applies to the step of forming the penetration electrode 33.

As shown in FIG. 8, the penetration electrode forming step S30A of the present embodiment includes a penetration hole (a recess portion) forming step S32 of forming a penetration hole (a recess portion) having a first opening on the first surface L of the base substrate wafer 40 and a metal pin disposing step S33 of inserting a metal pin into the penetration hole. The penetration electrode forming step S30A also includes a first glass frit filling step S35A of filling a first glass frit into the penetration hole and temporarily drying the first glass frit and a second glass frit filling step S35B of filling a second glass frit into the penetration hole to be overlapped on the first glass frit and temporarily drying the second glass frit. The penetration electrode forming step S30A also includes a baking step S37 of baking and curing the first and second glass frits filled in the penetration hole and a polishing step S39 of polishing at least the second surface of the first substrate so that the metal pin is exposed to the second surface.

### Penetration Hole Forming Step

FIG. 10 is a diagram illustrating a penetration hole.

In the penetration electrode forming step S30A, a penetration hole forming step S32 is performed in which the penetration hole 30 is formed in the base substrate wafer 40 so as to dispose a penetration electrode. The penetration hole 30 is formed by press working, a sand blast method, and the like. In the present embodiment, as shown in FIG. 10, the penetration hole 30 is formed by press working so that the inner shape thereof gradually increases from the second surface U side of the base substrate wafer 40 towards the first surface L side.

As the specific penetration hole forming step S32, first, a press mold is heated and pressed against the first surface L of the base substrate wafer 40. Here, a bowl-shaped recess portion is formed on the base substrate wafer 40 by a truncated conical projection formed on the press mold. After that, the second surface U of the base substrate wafer 40 is polished to remove the bottom surface of the recess portion, whereby the penetration hole 30 having a tapered inner surface is formed. In this way, the penetration hole forming step S32 ends.

In the present embodiment, although the cross section of the penetration hole 30 in the direction perpendicular to the central axis O has a circular shape, the cross section may have a rectangular shape, for example, by changing the shape of the projection on the press mold.

### Metal Pin Disposing Step

Subsequently, a metal pin disposing step S33 is performed in which a metal pin is inserted into the penetration hole 30.

FIGS. 11A and 11B are diagrams illustrating a metal pin, in which FIG. 11A is a perspective view and FIG. 11B is a sectional view taken along the line C-C in FIG. 11A.

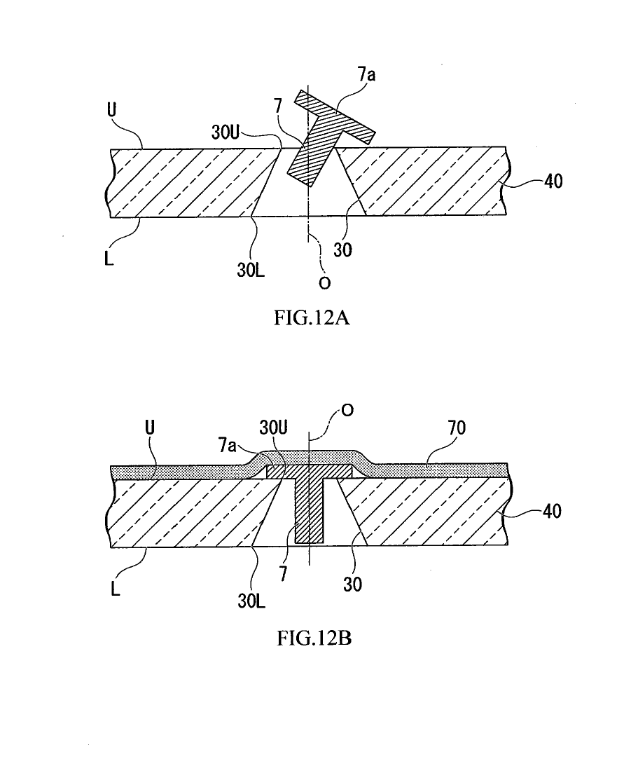

FIGS. 12A and 12B are diagrams illustrating a metal pin disposing step, in which FIG. 12A shows a state during the disposing and FIG. 12B shows a state after the disposing.

As shown in FIGS. 11A and 11B, a rivet member is formed by a metal pin 7 and a base portion 7a. The metal pin 7 stands up in a normal direction from the flat plate-like base portion 7a. When the metal pin 7 and the base portion 7a are formed, first, a rod-like member having the same diameter as the metal pin 7 is cut. After that, one end side of the rod-like member is processed by press working or forging to form the base portion 7a, and the other end side is cut, whereby the metal pin 7 is formed. In the present embodiment, the base portion 7a has an approximately disk-like shape. Moreover, the outer shape in top view of the base portion 7a is larger than the outer shape in top view of the metal pin 7 and is larger than the outer shape in top view of a second opening 30U. In this way, the metal pin 7 and the base portion 7a are formed.

In the metal pin disposing step S33, as shown in FIGS. 12A and 12B, the metal pin 7 is inserted from the second opening 30U of the base substrate wafer 40 so that the metal pin 7 is disposed in the penetration hole 30. As a specific metal pin disposing method, for example, a rivet member group is disposed on the second surface U of the base substrate wafer 40. Moreover, vibration is applied to the base substrate wafer 40 while shaking the base substrate wafer 40 to disperse the rivet member group, whereby the metal pin 7 is inserted into the penetration hole 30. The metal pin 7 may be disposed in the penetration hole 30 by disposing a plurality of metal pins 7 at positions corresponding to the penetration holes 30 using a jig and inserting the plurality of metal pins 7 from the second surface U side. Moreover, as shown in FIG. 12B, in the metal pin disposing step S33, the base portion 7a blocks the second opening 30U. The base portion 7a is disposed in a state of being in contact with the second surface U of the base substrate wafer 40.

After the metal pin 7 is disposed in the penetration hole 30, as shown in FIG. 12B, a laminate material 70 made of a paper tape is bonded to the second surface U side. In this way, it is possible to prevent falling of the metal pin 7 or leakage of the glass frit in steps subsequent to a glass frit filling step S35 described later. In this way, the metal pin disposing step S33 ends. After the laminate material 70 is bonded, the base substrate wafer 40 is turned upside down so that the first surface L side becomes the upper surface, and the glass frit filling step S35 is performed in which the glass frit is filled from the first surface L side.

### Glass Frit Filling Step

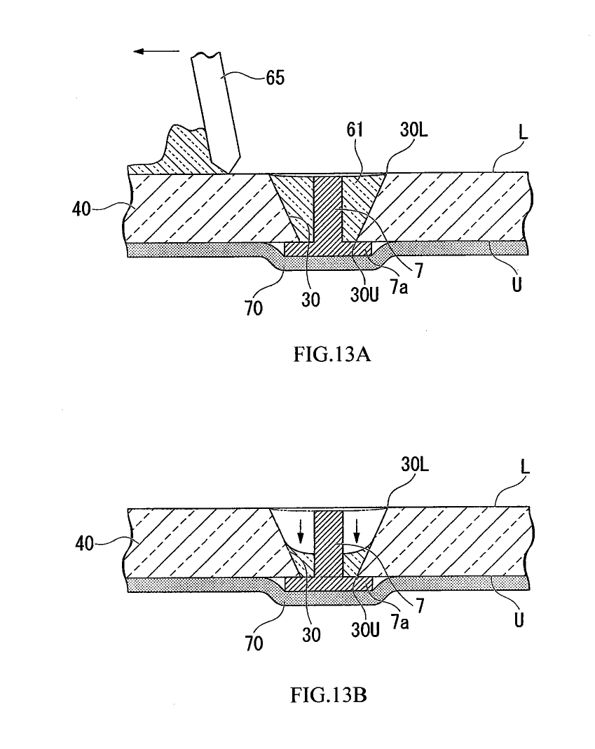

FIGS. 13A and 13B are diagrams illustrating a first glass frit filling step S35A of the glass frit filling step S35, in which FIG. 13A shows a state where a first glass frit is being filled and FIG. 13B shows a state after the glass frit is temporarily dried.

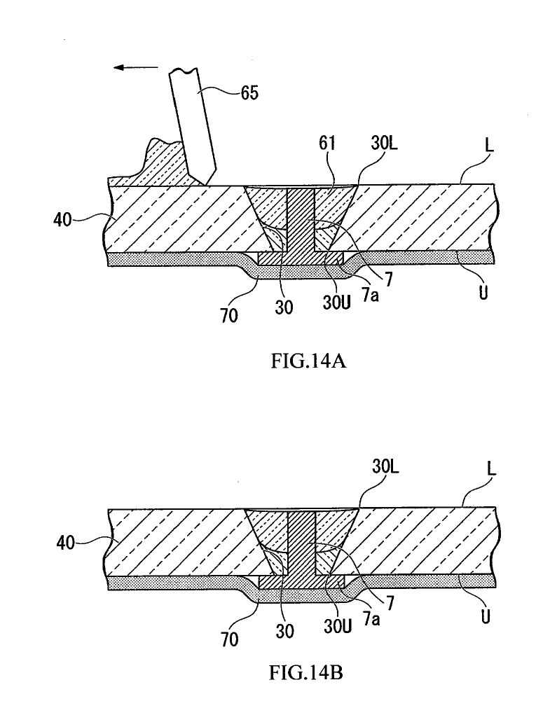

FIGS. 14A and 14B are diagrams illustrating a second glass frit filling step S35B of the glass frit filling step S35, in which FIG. 14A shows a state where a second glass frit is being filled and FIG. 14B shows a state after the glass frit is temporarily dried.

Subsequently, a glass frit filling step S35 is performed in which the first glass frit 61 and the second glass frit 63 are filled between the penetration hole 30 and the metal pin 7. The glass frit filling step S35 includes a first glass frit filling step S35A where the first glass frit 61 is filled into the penetration hole 30 and is temporarily dried, and a second glass frit filling step S35B where the second glass frit 63 is filled into the penetration hole 30 to be overlapped on the first glass frit 61 and is temporarily dried.

The first and second glass frits 61 and 63 are paste-like glass fits which are mainly made up of powder-like glass particles, an organic solvent, and ethyl cellulose used as a binder.

A second particle size of the second glass particles contained in the second glass fit 63 is larger than a first particle size of the first glass particles contained in the first glass frit 61. In the present embodiment, the first particle size of the first glass particles is 1 μm or less, and the second particle size of the second glass particles is about 2 μm to 4 μm. As described above, since the second particle size of the second glass particles is larger than the first particle size of the first glass particles, the heat capacity of the second glass particles is larger than the heat capacity of the first glass particles. Therefore, in a baking step S37 described later, the first glass particles are melted first, and then, the second glass particles are melted.

Moreover, the viscosity of the first glass frit 61 is set so as to be equal to or lower than the viscosity of the second glass frit 63. In the present embodiment, the viscosity of the first glass frit 61 is about 30 Pa·s, and the viscosity of the second glass frit 63 is about 60 Pa·s. The viscosities of the first and second glass frits 61 and 63 are mainly determined by the compounding ratio of the glass particles and the organic solvent. Specifically, the viscosity can be increased by increasing the compounding ratio of the glass particles and decreasing the compounding ratio of the organic solvent. Moreover, the viscosity can be decreased by decreasing the compounding ratio of the glass particles and increasing the compounding ratio of the organic solvent. The viscosity of the glass frit also changes in accordance with the size of the glass particles. When the organic solvents having the same viscosity are used, the viscosity increases if the glass particle size is small and the viscosity decreases if the glass particle size is large.

### First Glass Frit Filling Step

In the glass frit filling step S35, a first glass frit filling step S35A is performed in which the first glass frit 61 is filled in the penetration hole 30 and is temporarily dried. The first glass frit filling step S35A will be described in detail below.

Specifically, first, a metal mask (not shown) is disposed on the first surface L. The metal mask is formed so as to cover the peripheral portion of the first surface L in order to prevent the glass frit from curving its way to adhere onto the second surface U, and an opening is formed at the center thereof so as to apply the glass frit through the opening. Subsequently, the base substrate wafer 40 is transferred and set in a chamber (not shown) of a vacuum screen printer (not shown), and the inside of the chamber is depressurized to create a depressurized atmosphere. After that, the first glass frit 61 is applied from the first surface L side of the base substrate wafer 40. Since the outer shape of the first opening 30L on the first surface L side of the penetration hole is larger than the outer shape of the second opening 30U on the second surface U side, the first glass frit 61 can be easily filled into the penetration hole 30. At that time, since the inside of the chamber is depressurized to about 1 torr, the first glass frit 61 is degassed, and bubbles included in the first glass frit 61 are removed.

Subsequently, as shown in FIG. 13A, a squeegee 65 is moved on the metal mask along the first surface L while bringing the tip end of the squeegee 65 into contact with the first surface L of the base substrate wafer 40. In this way, the first glass frit 61 is moved to be pushed into the penetration hole 30 by the tip end of the squeegee 65, and the first glass frit 61 is filled into the penetration hole 30. Here, the viscosity of the first glass frit 61 is set to be as low as about 30 Pa·s as described above. Therefore, since the first glass frit 61 has good mobility, the first glass frit 61 can be dispersed to every corner of the gap between the penetration hole 30 and the metal pin 7, and the occurrence of voids in the penetration electrode can be prevented. As described above, the laminate material 70 is bonded to the second surface U in a state where the second opening 30U is blocked by the base portion 7a, and the base portion 7a is in contact with the second surface U of the base substrate wafer 40. In this way, the first glass frit 61 can be filled from the first surface L side while preventing the first glass frit 61 from leaking from the second surface U side of the base substrate wafer 40.

After that, the first glass frit 61 is temporarily dried. For example, after the base substrate wafer 40 is transferred into a chamber maintained at a constant temperature, by maintaining the base substrate wafer 40 under an atmosphere of about 85° C. for about 30 minutes, the first glass frit 61 is temporarily dried. The melting temperature of the glass particles is generally about 400° C. to about 500° C., which is far higher than 85° C. which is the temperature during the temporary drying. Therefore, the first glass frit 61 will not be melted during the temporary drying. On the other hand, the boiling point of the organic solvent compounded in the first glass frit 61 is lower than 85° C. Therefore, the organic solvent will be evaporated to some extent and become gases during the temporary drying. Although ethyl cellulose is also compounded in the first glass frit 61, the boiling point of ethyl cellulose is about 350° C. which is far higher than 85° C. which is the temperature during the temporary drying. Therefore, ethyl cellulose will not be evaporated during the temporary drying.

Here, since the first glass particles of the first glass frit 61 are not melted, a gap is present between the glass particles. Therefore, the gas generated when the organic solvent is evaporated will pass through the gap between the first glass particles and be discharged outside the first glass frit 61.

When the first glass frit 61 is temporarily dried, the volume of the first glass frit 61 decreases as shown in FIG. 13B. As described above, the viscosity of the first glass frit 61 is set to be relatively low, and the compounding ratio of the organic solvent compounded in the first glass frit 61 is high. Therefore, when the organic solvent is evaporated through the temporary drying, the volume of the first glass frit 61 will decrease greatly. After the temporary drying, the residues of the redundant first glass frit 61 adhering on the first surface L of the base substrate wafer 40 are removed. The first glass frit filling step S35A ends at this point in time.

### Second Glass Frit Filling Step

Subsequently, in the glass frit filling step S35, the second glass frit filling step S35B is performed in which the second glass frit 63 having a large particle size is filled to be overlapped on the dried first glass frit 61 and is temporarily dried. As shown in FIG. 14A, similarly to the first glass frit filling step S35A, the squeegee 65 is moved on the metal mask along the first surface L under a depressurized atmosphere, whereby the second glass frit 63 is filled into the penetration hole 30 and is temporarily dried.

Here, the viscosity of the second glass frit 63 is set to about 60 Pa·s as described above. Therefore, the second glass frit 63 has higher viscosity than the first glass frit 61 and poorer mobility than the first glass frit 61. However, through the first glass frit filling step S35A described above, the first glass frit 61 is dispersed and filled over a wide area to every corner of the gap between the penetration hole 30 and the metal pin 7 in the vicinity of the second small-diameter opening 30U. Therefore, in the second glass frit filling step S35B, it is only necessary to fill the second glass frit 63 into a relatively wide gap between the penetration hole 30 and the metal pin 7 in the vicinity of the first large-diameter opening 30L. Thus, even when the second glass frit 63 has high viscosity, the second glass frit 63 can be filled to every corner of the gap between the penetration hole 30 and the metal pin 7.

After that, similarly to the first glass frit filling step S35A, the second glass frit 63 is temporarily dried by leaving it under an atmosphere of about 85° C. for about 30 minutes. Since the compounding ratio of the organic solvent compounded in the second glass frit 63 is low, even when the organic solvent is evaporated through the temporary drying, the volume of the second glass frit 63 will be rarely reduced. After the temporary drying, the residues of the redundant second glass frit 63 adhering on the first surface L of the base substrate wafer 40 are removed. The second glass frit filling step S35B ends at this point in time.

### Baking Step

FIG. 15 is a diagram illustrating a baking step S37. For better understanding of the drawing, the size of the first glass particles 61a of the first glass frit 61 and the size of the second glass particles 63a of the second glass frit 63 are exaggerated.

Subsequently, a baking step S37 is performed in which the first and second glass frits 61 and 63 filled into the penetration hole 30 are baked and cured. For example, after the base substrate wafer 40 is transferred to a baking furnace, the base substrate wafer 40 is maintained under an atmosphere of about 610° C. for about 30 minutes, whereby the first and second glass frits 61 and 63 are baked.

As shown in FIG. 15, the second particle size of the second glass particles 63a contained in the second glass frit 63 is larger than the first particle size of the first glass particles 61a contained in the first glass frit 61. Therefore, the heat capacity of the second glass particles 63a is larger than the heat capacity of the first glass particles 61a. Thus, the central portions of the first glass particles 61a reach about 400° C. to about 500° C., which is the melting point of the glass particles, earlier than the central portions of the second glass particles 63a, and the melting of the first glass particles 61a ends earlier than the melting of the second glass particles 63a. Since the boiling point of ethyl cellulose contained in the glass frit is about 350° C. as described above, ethyl cellulose is evaporated from the first and second glass frits 61 and 63 during the baking, whereby gases such as carbon monoxide (CO), carbon dioxide (CO₂), or water vapor (H₂O) are generated.

Here, the first glass frit is filled on the bottom side (that is, the second opening 30U side) of the recess portion formed by the base portion 7a and the penetration hole 30, and the second glass fit is filled on the first opening 30L side. Therefore, the gases generated from the first glass fit 61 pass through a gap 63b between the second glass particles 63a and are discharged outside from the first opening 30L while preventing the second glass frit 63 from acting as a lid. In this way, since it is hard for bubbles generated by the gases to remain in the first and second glass frits 61 and 63, it is possible to prevent the occurrence of voids in the glass after the glass frit baking. Therefore, since the penetration hole 30 and the metal pin 7 are effectively closely adhered to the baked glass without generating voids, it is possible to form the penetration electrode without conduction defects while maintaining the airtightness of the cavity.

After that, the melting of the second glass frit 63 proceeds following the first glass frit 61. As described above, by maintaining the glass frit under an atmosphere of about 610° C. for about 30 minutes, the baking of the first and second glass frits 61 and 63 is completed. After the baking is completed, the base substrate wafer 40 is maintained under a room-temperature atmosphere and cooled. As a result, the first and second glass frits 61 and 63 are solidified, and the penetration hole 30, the first and second glass frits 61 and 63, and the metal pin 7 are attached to each other, whereby the penetration electrode can be formed. In this way, the baking step S37 ends.

### Polishing Step

Subsequently, as shown in FIG. 14, a polishing step S39 is performed in which at least the second surface U of the base substrate wafer 40 is polished so as to expose the metal pin 7 to the second surface U. By polishing the second surface U, it is possible to remove the base portion 7a and allow the metal pin 7 to remain inside the cylindrical member 6. Moreover, it is preferable to polish the first surface L in addition to the second surface. In this way, it is possible to make the first surface L flat and reliably expose the tip end of the metal pin 7. As a result, it is possible to make the surface of the base substrate wafer 40 approximately flush with both ends of the metal pin 7 and obtain a plurality of penetration electrodes 32. The penetration electrode forming step S30A ends at a point in time when the polishing step S39 is performed.

After that, returning to FIG. 9, a lead-out electrode forming step S40 is performed in which a plurality of lead-out electrodes 36 and 37 is formed on the second surface U so as to be electrically connected to the penetration electrodes, respectively. In addition, tapered bumps made of Au or the like are formed on the lead-out electrodes 36 and 37. In FIG. 9, illustrations of the bumps are omitted to make the drawing easier to see. The base substrate wafer manufacturing step S30 ends at this point in time.

### Piezoelectric Vibrator Assembling Step Subsequent to Mounting Step S50

Subsequently, a mounting step S50 is performed in which the piezoelectric vibrating reeds 4 are bonded to the lead-out electrodes 36 and 37 of the base substrate wafer 40 by the bumps B. Specifically, the base portions 12 of the piezoelectric vibrating reeds 4 are placed on the bumps B, and an ultrasonic vibration is applied while pressing the piezoelectric vibrating reeds 4 against the bumps B and heating the bumps B to a predetermined temperature. In this way, as shown in FIG. 3, the base portions 12 are mechanically fixed to the bumps B in a state where the vibrating arms 10 and 11 of the piezoelectric vibrating reed 4 are floated from the second surface U of the base substrate wafer 40. Moreover, the mount electrodes 16 and 17 are electrically connected to the lead-out electrodes 36 and 37.

After the mounting of the piezoelectric vibrating reed 4 is completed, as shown in FIG. 10, a superimposition step S60 is performed in which the lid substrate wafer 50 is superimposed onto the base substrate wafer 40. Specifically, the two wafers 40 and 50 are aligned at a correct position using reference marks (not shown) or the like as indices. In this way, the piezoelectric vibrating reed 4 mounted on the base substrate wafer 40 is accommodated in the cavity C which is surrounded by the recess portion 3a for the cavity of the lid substrate wafer 50 and the base substrate wafer 40.

After the superimposition step S60 is performed, a bonding step S70 is performed in which the two superimposed wafers 40 and 50 are inserted into an anodic bonding machine (not shown) to achieve anodic bonding under a predetermined temperature atmosphere with application of a predetermined voltage. Specifically, a predetermined voltage is applied between the bonding film 35 and the base substrate wafer 40. Then, an electrochemical reaction occurs at an interface between the bonding film 35 and the base substrate wafer 40, whereby they are closely and tightly adhered and anodically bonded. In this way, the piezoelectric vibrating reed 4 can be sealed in the cavity C, and a wafer assembly 60 in which the base substrate wafer 40 and the lid substrate wafer 50 are bonded to each other can be obtained as shown in FIG. 10. In FIG. 10, for better understanding of the drawing, the wafer assembly 60 is illustrated in an exploded state, and illustration of the bonding film 35 is omitted from the lid substrate wafer 50.

Subsequently, an outer electrode forming step S80 is performed in which a conductive material is patterned onto the first surface L of the base substrate wafer 40 so as to form a plurality of pairs of outer electrodes 38 and 39 (see FIG. 3) which is electrically connected to the pair of penetration electrodes 32 and 33. Through this step, the piezoelectric vibrating reed 4 is electrically connected to the outer electrodes 38 and 39 through the penetration electrodes 32 and 33.

Subsequently, a fine tuning step S90 is performed on the wafer assembly 60 where the frequencies of the individual piezoelectric vibrators sealed in the cavities C are tuned finely to fall within a predetermined range. Specifically, a predetermined voltage is continuously applied to the outer electrodes 38 and 39 shown in FIG. 4 to allow the piezoelectric vibrating reeds 4 to vibrate, and the vibration frequency is measured. In this state, a laser beam is irradiated onto the base substrate wafer 40 from the outer side so as to evaporate the fine tuning film 21b of the weight metal film 21 shown in FIGS. 5 and 6. In this way, since the weight on the tip end sides of the pair of vibrating arms 10 and 11 decreases, the frequency of the piezoelectric vibrating reed 4 increases. By so doing, the frequency of the piezoelectric vibrator can be finely tuned so as to fall within the range of the nominal frequency.

After the fine tuning of the frequency is completed, a cutting step S100 is performed in which the bonded wafer assembly 60 is cut along the cutting line M shown in FIG. 10. Specifically, first, a UV tape is attached on the surface of the base substrate wafer 40 of the wafer assembly 60. Subsequently, a laser beam is irradiated along the cutting line M from the side of the lid substrate wafer 50 (scribing). Subsequently, the wafer assembly 60 is divided and cut along the cutting line M by a cutting blade pressing against the surface of the UV tape (breaking). After that, the UV tape is separated by irradiation of UV light. In this way, it is possible to divide the wafer assembly 60 into a plurality of piezoelectric vibrators. The wafer assembly 60 may be cut by other methods such as dicing.

Moreover, the fine tuning step S90 may be performed after cutting the wafer assembly into pieces of individual piezoelectric vibrators in the cutting step S100. However, as described above, the fine tuning can be performed in a state of the wafer assembly 60 by performing the fine tuning step S90 first. Therefore, in the case of performing the fine tuning step S90 first, a plurality of piezoelectric vibrators can be finely tuned more efficiently. This is preferable since the throughput can be improved.

Then, an inner electrical property test S110 is performed. That is, resonance frequency, resonant resistance value, drive level characteristics (exciting power dependency of resonance frequency and resonant resistance value), and the like of the piezoelectric vibrating reed 4 are checked by measurement. Moreover, an insulation resistance characteristic and the like are checked together. Finally, visual inspection of the piezoelectric vibrator is performed to finally check the dimension, quality, and the like. Thus, the manufacturing of the piezoelectric vibrator ends.

According to the present embodiment, as shown in FIG. 15, since the second particle size of the second glass particles 63a is larger than the first particle size of the first glass particles 61a, the heat capacity of the second glass particles 63a is larger than the heat capacity of the first glass particles 61a. Therefore, in the baking step, the melting of the second glass particles 63a is completed later than the melting of the first glass particles 61a. Moreover, since the second glass frit 63 is filled to be overlapped on the first glass frit 61, the first glass frit 61 is filled on the second opening 30U side of the penetration hole 30, and the second glass frit 63 is filled on the first opening 30L side of the penetration hole 30. Therefore, the gases generated from the first glass frit 61 pass through a gap 63b between the second glass particles 63a and are discharged outside from the first opening 30L of the penetration hole 30 while preventing the second glass frit 63 from acting as a lid. In this way, since it is hard for bubbles generated by the gases to remain in the first and second glass frits 61 and 63, it is possible to prevent the occurrence of voids in the glass after the glass frit baking. Therefore, since the penetration hole 30 and the metal pin 7 are effectively and closely adhered to the baked glass without generating voids, it is possible to form the penetration electrode without conduction defects while maintaining the airtightness of the cavity.

### Oscillator

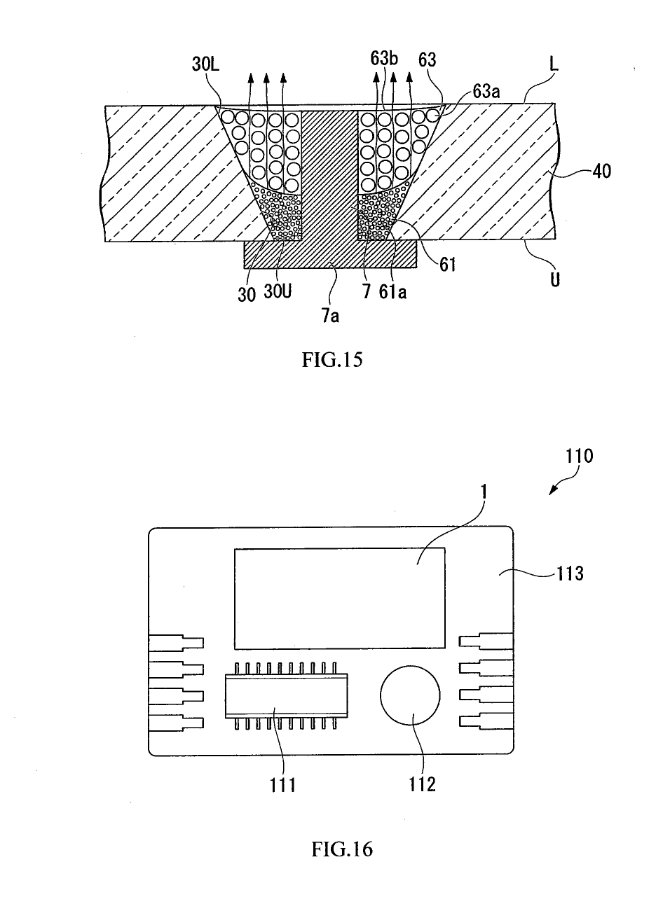

Next, an oscillator according to another embodiment of the invention will be described with reference to FIG. 16.

In an oscillator 110 according to the present embodiment, the piezoelectric vibrator 1 is used as an oscillating piece electrically connected to an integrated circuit 111, as shown in FIG. 16. The oscillator 110 includes a substrate 113 on which an electronic component 112, such as a capacitor, is mounted. The integrated circuit 111 for an oscillator is mounted on the substrate 113, and the piezoelectric vibrating reed of the piezoelectric vibrator 1 is mounted near the integrated circuit 111. The electronic component 112, the integrated circuit 111, and the piezoelectric vibrator 1 are electrically connected to each other by a wiring pattern (not shown). In addition, each of the constituent components is molded with a resin (not shown).

In the oscillator 110 configured as described above, when a voltage is applied to the piezoelectric vibrator 1, the piezoelectric vibrating reed in the piezoelectric vibrator 1 vibrates. This vibration is converted into an electrical signal due to the piezoelectric property of the piezoelectric vibrating reed and is then input to the integrated circuit 111 as the electrical signal. The input electrical signal is subjected to various kinds of processing by the integrated circuit 111 and is then output as a frequency signal. In this way, the piezoelectric vibrator 1 functions as an oscillating piece.

Moreover, by selectively setting the configuration of the integrated circuit 111, for example, an RTC (real time clock) module, according to the demands, it is possible to add a function of controlling the operation date or time of the corresponding device or an external device or of providing the time or calendar in addition to a single functional oscillator for a timepiece.

As described above, since the oscillator 110 according to the present embodiment includes the piezoelectric vibrator 1 which is manufactured by a manufacturing method capable of securing reliable conduction of the penetration electrode while maintaining the airtightness of the cavity, the oscillator 110 having excellent performance and superior reliability can be provided.

### Electronic Apparatus

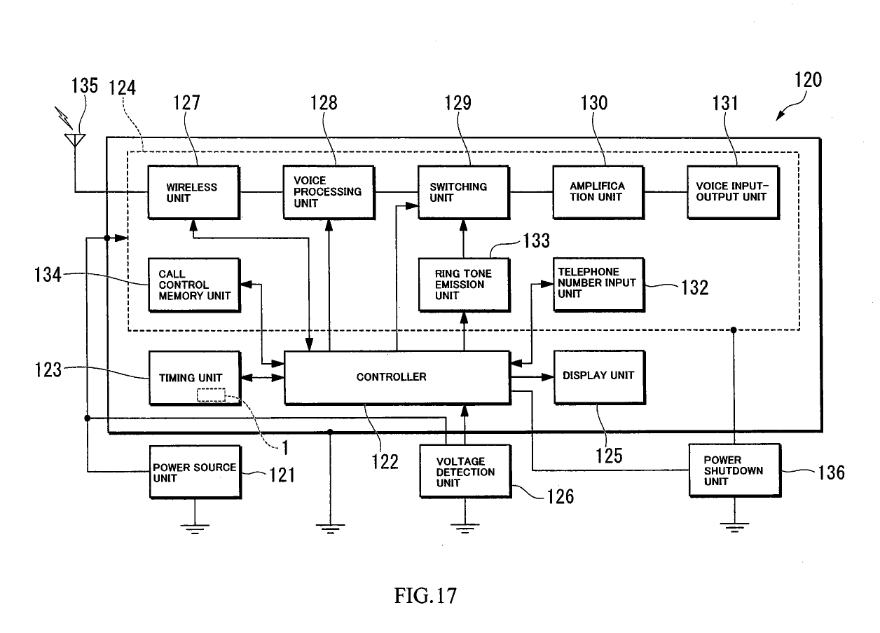

Next, an electronic apparatus according to another embodiment of the invention will be described with reference to FIG. 17. In addition, a portable information device 120 including the piezoelectric vibrator 1 will be described as an example of an electronic apparatus.

The portable information device 120 according to the present embodiment is represented by a mobile phone, for example, and has been developed and improved from a wristwatch in the related art. The portable information device 120 is similar to a wristwatch in external appearance, and a liquid crystal display is disposed in a portion equivalent to a dial pad so that a current time and the like can be displayed on this screen. Moreover, when it is used as a communication apparatus, it is possible to remove it from the wrist and to perform the same communication as a mobile phone in the related art with a speaker and a microphone built in an inner portion of the band. However, the portable information device 120 is very small and light compared with a mobile phone in the related art.

Next, the configuration of the portable information device 120 according to the present embodiment will be described. As shown in FIG. 17, the portable information device 120 includes the piezoelectric vibrator 1 and a power supply section 121 for supplying power. The power supply section 121 is formed of a lithium secondary battery, for example. A control section 122 which performs various kinds of control, a clock section 123 which performs counting of time and the like, a communication section 124 which performs communication with the outside, a display section 125 which displays various kinds of information, and a voltage detecting section 126 which detects the voltage of each functional section are connected in parallel to the power supply section 121. In addition, the power supply section 121 supplies power to each functional section.

The control section 122 controls an operation of the entire system. For example, the control section 122 controls each functional section to transmit and receive the audio data or to measure or display a current time. In addition, the control section 122 includes a ROM in which a program is written in advance, a CPU which reads and executes a program written in the ROM, a RAM used as a work area of the CPU, and the like.

The clock section 123 includes an integrated circuit, which has an oscillation circuit, a register circuit, a counter circuit, and an interface circuit therein, and the piezoelectric vibrator 1. When a voltage is applied to the piezoelectric vibrator 1, the piezoelectric vibrating reed vibrates, and this vibration is converted into an electrical signal due to the piezoelectric property of crystal and is then input to the oscillation circuit as the electrical signal. The output of the oscillation circuit is binarized to be counted by the register circuit and the counter circuit. Then, a signal is transmitted to or received from the control section 122 through the interface circuit, and current time, current date, calendar information, and the like are displayed on the display section 125.

The communication section 124 has the same function as a mobile phone in the related art, and includes a wireless section 127, an audio processing section 128, a switching section 129, an amplifier section 130, an audio input/output section 131, a telephone number input section 132, a ring tone generating section 133, and a call control memory section 134.

The wireless section 127 transmits/receives various kinds of data, such as audio data, to/from the base station through an antenna 135. The audio processing section 128 encodes and decodes an audio signal input from the wireless section 127 or the amplifier section 130. The amplifier section 130 amplifies a signal input from the audio processing section 128 or the audio input/output section 131 up to a predetermined level. The audio input/output section 131 is formed by a speaker, a microphone, and the like, and amplifies a ring tone or incoming sound loudly or collects the sound.

In addition, the ring tone generating section 133 generates a ring tone in response to a call from the base station. The switching section 129 switches the amplifier section 130, which is connected to the audio processing section 128, to the ring tone generating section 133 only when a call arrives, so that the ring tone generated in the ring tone generating section 133 is output to the audio input/output section 131 through the amplifier section 130.

In addition, the call control memory section 134 stores a program related to incoming and outgoing call control for communications. Moreover, the telephone number input section 132 includes, for example, numeric keys from 0 to 9 and other keys. The user inputs a telephone number of a communication destination by pressing these numeric keys and the like.

The voltage detecting section 126 detects a voltage drop when a voltage, which is applied from the power supply section 121 to each functional section, such as the control section 122, drops below the predetermined value, and notifies the control section 122 of the detection. In this case, the predetermined voltage value is a value which is set beforehand as the lowest voltage necessary to operate the communication section 124 stably. For example, it is about 3 V. When the voltage drop is notified from the voltage detecting section 126, the control section 122 disables the operation of the wireless section 127, the audio processing section 128, the switching section 129, and the ring tone generating section 133. In particular, the operation of the wireless section 127 that consumes a large amount of power should be necessarily stopped. In addition, a message informing that the communication section 124 is not available due to insufficient battery power is displayed on the display section 125.

That is, it is possible to disable the operation of the communication section 124 and display the notice on the display section 125 by the voltage detecting section 126 and the control section 122. This message may be a character message. Or as a more intuitive indication, a cross mark (X) may be displayed on a telephone icon displayed at the top of the display screen of the display section 125.

In addition, the function of the communication section 124 can be more reliably stopped by providing a power shutdown section 136 capable of selectively shutting down the power of a section related to the function of the communication section 124.

As described above, since the portable information device 120 according to the present embodiment includes the piezoelectric vibrator 1 which is manufactured by a manufacturing method capable of securing reliable conduction of the penetration electrode while maintaining the airtightness of the cavity, the portable information device 120 having excellent performance and superior reliability can be provided.

### Radio-Controlled Timepiece

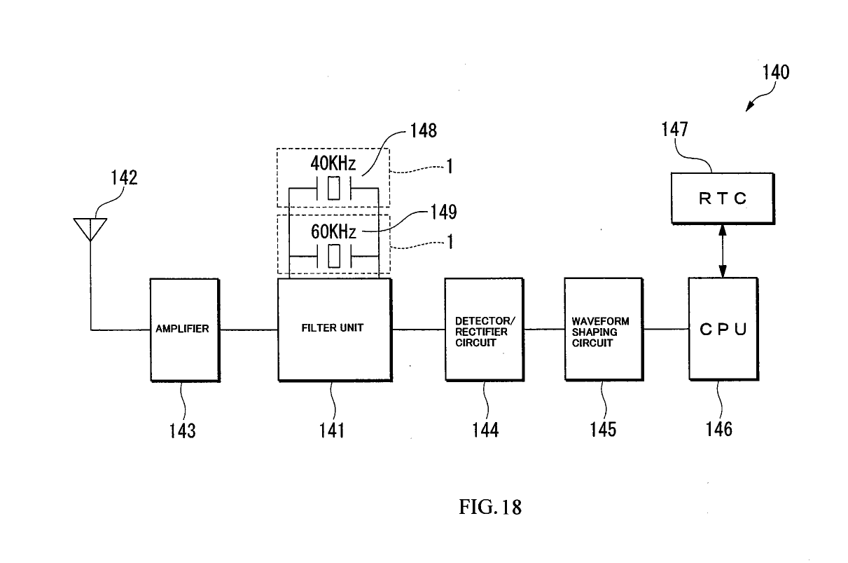

Next, a radio-controlled timepiece according to still another embodiment of the invention will be described with reference to FIG. 18.

As shown in FIG. 18, a radio-controlled timepiece 140 according to the present embodiment includes the piezoelectric vibrators 1 electrically connected to a filter section 141. The radio-controlled timepiece 140 is a timepiece with a function of receiving a standard radio wave including the clock information, automatically changing it to the correct time, and displaying the correct time.

In Japan, there are transmission centers (transmission stations) that transmit a standard radio wave in Fukushima Prefecture (40 kHz) and Saga Prefecture (60 kHz), and each center transmits the standard radio wave. A long wave with a frequency of, for example, 40 kHz or 60 kHz has both a characteristic of propagating along the land surface and a characteristic of propagating while being reflected between the ionospheric layer and the land surface, and therefore has a propagation range wide enough to cover the entire area of Japan through the two transmission centers.

Hereinafter, the functional configuration of the radio-controlled timepiece 140 will be described in detail.

An antenna 142 receives a long standard radio wave with a frequency of 40 kHz or 60 kHz. The long standard radio wave is obtained by performing AM modulation of the time information, which is called a time code, using a carrier wave with a frequency of 40 kHz or 60 kHz. The received long standard wave is amplified by an amplifier 143 and is then filtered and synchronized by the filter section 141 having the plurality of piezoelectric vibrators 1.

In the present embodiment, the piezoelectric vibrators 1 include crystal vibrator sections 148 and 149 having resonance frequencies of 40 kHz and 60 kHz, respectively, which are the same frequencies as the carrier frequency.

In addition, the filtered signal with a predetermined frequency is detected and demodulated by a detection and rectification circuit 144.

Then, the time code is extracted by a waveform shaping circuit 145 and counted by the CPU 146. The CPU 146 reads the information including the current year, the total number of days, the day of the week, the time, and the like. The read information is reflected on an RTC 148, and the correct time information is displayed.

Because the carrier wave is 40 kHz or 60 kHz, a vibrator having the tuning fork structure described above is suitable for the crystal vibrator sections 148 and 149.

Moreover, although the above explanation has been given for the case in Japan, the frequency of a long standard wave is different in other countries. For example, a standard wave of 77.5 kHz is used in Germany. Therefore, when the radio-controlled timepiece 140 which is also operable in other countries is assembled in a portable device, the piezoelectric vibrator 1 corresponding to frequencies different from the frequencies used in Japan is necessary.

As described above, since the radio-controlled timepiece 140 according to the present embodiment includes the piezoelectric vibrator 1 which is manufactured by a manufacturing method capable of securing reliable conduction of the penetration electrode while maintaining the airtightness of the cavity, the radio-controlled timepiece 140 having excellent performance and superior reliability can be provided.

The present invention is not limited to the above-described embodiments.

In the present embodiment, the method of manufacturing a package according to the present invention has been described by way of an example of a piezoelectric vibrator using, for example, a tuning-fork type piezoelectric vibrating reed. However, the method of manufacturing a package according to the present invention may be applied to a piezoelectric vibrator using an AT-cut type piezoelectric vibrating reed (a thickness-shear type vibrating reed).

In the present embodiment, a piezoelectric vibrator was manufactured by sealing a piezoelectric vibrating reed in a package using the method of manufacturing a package according to the present invention. However, a device other than the piezoelectric vibrator may be manufactured by sealing an electronic component other than the piezoelectric vibrating reed in a package.

In the present embodiment, each of the first and second glass fit filling steps is performed only once in the glass frit filling step. However, after the second glass frit filling step is performed, the second glass frit may be filled in an overlapped manner. In this way, it is possible to prevent the occurrence of depressions on the surface of the penetration electrode generated by the evaporation of the organic solvent.

In the present embodiment, the penetration electrode is formed by disposing the metal pin standing up from the base portion in the penetration hole and then polishing and removing the base portion. However, the penetration electrode may be formed by forming the penetration hole as a bottomed recess portion and disposing the columnar metal pin in the recess portion. However, the present embodiment is superior in that the metal pin can be disposed without being tilted in the penetration hole.

What is claimed is:

1. A method for producing piezoelectric vibrators, comprising:
(a) defining a plurality of first substrates on a first wafer and a plurality of second substrates on a second wafer;
(b) forming a pair of through-holes in a respective at least some of the first substrates on the first wafer;
(c) filling at least some of the through-holes with first and second types of filler in layers;
(d) layering the first and second wafers such that at least some of the first substrates substantially coincide respectively with at least some of the corresponding second substrates, wherein a piezoelectric vibrating strip is secured in a respective at least some of coinciding first and second substrates;
(e) cutting off a respective at least some of packages made of coinciding first and second substrates.

2. The method according to claim 1, wherein the first and second types of filler are both glass fit paste.

3. The method according to claim 1, wherein the first and second types of filler comprise glass particles of different sizes.

4. The method according to claim 3, wherein the glass particles in the first type of filler have sizes of 1 μm or less, whereas the glass particles in the second type of filler have sizes of about 2 μm to about 4 μm.

5. The method according to claim 3, wherein the first and second types of filler further comprise an organic solvent and a binder.

6. The method according to claim 5, wherein the binder is ethyl cellulose.

7. The method according to claim 5, wherein the first and second types of filler have different ratios of the glass particles and the organic solvent to have different viscosities.

8. The method according to claim 7, wherein the first type of filler has a viscosity of about 30 Pa·s, and the second type of filler has a viscosity of about 60 Pa·s.

9. The method according to claim 1, wherein the first and second types of filler have different viscosities.

10. The method according to claim 1, wherein filling at least some of the through-holes with first and second types of filler in layers comprises first placing the first type of filler in at least some of the through-holes and then placing the second type of filler in at least some of the through-holes in which the first type of filler is placed.

11. The method according to claim 10, wherein placing the first type of filler in at least some of the through-holes and placing the second type of filler in at least some of the through-holes in which the first type of filler is placed each comprise squeegeeing the filler in the through-holes in a low pressure atmosphere.

12. The method according to claim 11, wherein the low pressure atmosphere is about 1 torr.

13. The method according to claim 10, wherein placing the first type of filler in at least some of the through-holes and placing the second type of filler in at least some of the through-holes in which the first type of filler is placed each comprise drying the filler in the through-holes.

14. The method according to claim 13, wherein drying the filler comprising heating the filler at about 85° C.

15. The method according to claim 1, further comprising baking the first wafer between steps (c) and (d).

16. The method according to claim 15, wherein baking the first wafer comprises heating the first wafer at a temperature of about 610° C.

17. The method according to claim 16, wherein heating the first wafer comprises heating the first wafer for about 30 minutes.

18. A piezoelectric vibrator comprising:
a hermetically closed casing comprising first and second substrates with a cavity inside, the first substrate being formed with a pair of through-holes which are closed with layers of first and second types of filler hardened by baking; and
a piezoelectric vibrating strip secured inside the cavity and electrically connected via a conductive pattern to the fillers in the through-holes.

19. The piezoelectric vibrator according to claim 18, wherein the first and second types of filler contain melted glass frits made from glass particles having different sizes.

20. An oscillator comprising the piezoelectric vibrator defined in claim 6.

21. An electronic device comprising a clock connected with the piezoelectric vibrator defined in claim 18.

22. An electronic device comprising a filter connected with the piezoelectric vibrator defined in claim 18.
